(19) United States
(12) Patent Application Publication
(10) Pub. No.: US 2013/0293318 A1
(43) Pub. Date: Nov. 7, 2013

(54) BANDPASS FILTER OF RF COMMUNICATION SYSTEM

(71) Applicant: ELECTRONICS AND TELECOMMUNICATIONS RESEARCH INSTITUTE, (US)

(72) Inventors: Ju Yeon HONG, Daejeon (KR); Young Jun CHONG, Daejeon (KR)

(73) Assignee: ELECTRONICS AND TELECOMMUNICATIONS RESEARCH INSTITUTE, Daejeon (KR)

(21) Appl. No.: 13/753,649

(22) Filed: Jan. 30, 2013

(30) Foreign Application Priority Data
May 3, 2012 (KR) 10-2012-0047079

(51) Int. Cl. H03H 7/01

(52) U.S. Cl. CPC H03H 7/0115
USPC 333/175

(57) ABSTRACT

The present invention relates to the bandpass filter of an RF communication system. The bandpass filter embodies a dual band characteristic by combining an equilibrium zero-order resonator and a non-equilibrium zero-order resonator, provides transmission zero using a cross-coupling structure near a pass band, and also has a neighboring signal blocking characteristic.

### CROSS-REFERENCES TO RELATED APPLICATIONS

The present application claims priority under 35 U.S.C 119(a) to Korean Application No. 10-2012-0047079, filed on May 3, 2012, in the Korean Intellectual Property Office, which is incorporated herein by reference in its entirety set forth in full.

### BACKGROUND

An exemplary embodiment of the present invention relates to the bandpass filter of a Radio Frequency (RF) communication system, and more particularly, to the bandpass filter of an RF communication system which is capable of embody a dual band characteristic by combining an equilibrium zero-order resonator and a non-equilibrium zero-order resonator and providing a transmission zero using a cross-coupling structure near a pass band.

Today, a portable wireless terminal has been rooted as a necessary article in everyday life, and consumers' interest in and demand for the radio industry, in particular, portable terminals locally and abroad. In line with this trend, active research is being carried out on the improvements of the performance and function of the terminal.

Meanwhile, in order for the terminal to be easily used while moving, the size and weight of the terminal must be reduced because the terminal must be small and light while not affecting its performance and functions. In particular, active research is being carried out on a reduction in the size and weight of the terminal because a reduction in the size of communication components secures a space on which other electronic components will be mounted, leading to the multi-functionality of the terminal.

A communication system basically requires a bandpass function and a band blocking function for transmission and reception RF signals depending on a specific frequency band. A bandpass filter is necessary to perform the functions.

In particular, the bandpass frequency of the bandpass filter is determined by an inductance component and a capacitance component of a filter resonator equivalent circuit model, a signal of a desired frequency band is transferred, and thus a function of distinguishing an in-band signal and an out-band signal from each other is provided to an RF communication system.

Meanwhile, in a communication system, in order to transmit and receive signals more precisely, the characteristics of the bandpass filter are important factors. In particular, in the existing communication system for transmitting and receiving signals in a multi-band frequency, there is a need for a bandpass filter capable of satisfying various needs, such as neighboring signal blocking and multi-band signal filtering.

As a related prior art, there is Korean Patent Laid-Open Publication No. 10-2011-0113340 (Oct. 17, 2011), entitled ‘BAND PASS FILTER AND DUPLEXER BASED ON CRLH RESONATORS’.

### SUMMARY

An embodiment of the present invention relates to the bandpass filter of an RF communication system which is capable of embody a dual band characteristic by combining an equilibrium zero-order resonator and a non-equilibrium zero-order resonator and providing a transmission zero using a cross-coupling structure near a pass band.

Another embodiment of the present invention relates to the bandpass filter of an RF communication system having a neighboring signal blocking characteristic.

In one embodiment, the bandpass filter of an RF communication system includes a first non-equilibrium zero-order resonator and a first equilibrium zero-order resonator connected in series to an input port; a second non-equilibrium zero-order resonator and a second equilibrium zero-order resonator connected in series to an output port; an induction coupling unit configured to combine the first equilibrium zero-order resonator and the second equilibrium zero-order resonator; and a cross-coupling unit connected in parallel to and branched from the first equilibrium zero-order resonator and the second equilibrium zero-order resonator.

In the present invention, in the first equilibrium zero-order resonator, a first serial resonance unit and a first parallel resonance unit, and a first serial inductor of the induction coupling unit have an equilibrium state. The first non-equilibrium zero-order resonator includes the first serial resonance unit and a second parallel resonance unit.

In the present invention, the first serial resonance unit includes a serial inductor and a serial capacitor.

In the present invention, the cross-coupling unit is branched from a node of the serial inductor of the first serial resonance unit and the serial capacitor and is connected by a serial capacitor.

In the present invention, each of the first parallel resonance unit and the second parallel resonance unit comprise a parallel inductor and a parallel capacitor

In the present invention, in the second equilibrium zero-order resonator, a second serial resonance unit and a third parallel resonance unit, and a second serial inductor of the induction coupling unit have an equilibrium state. The second non-equilibrium zero-order resonator includes the second serial resonance unit and a fourth parallel resonance unit.

In the present invention, the second serial resonance unit includes a serial inductor and a serial capacitor.

In the present invention, the cross-coupling unit is branched from a node of the serial inductor of the second serial resonance unit and the serial capacitor and is connected by a serial capacitor.

In the present invention, each of the third parallel resonance unit and the fourth parallel resonance unit comprise a parallel inductor and a parallel capacitor.

### BRIEF DESCRIPTION OF THE DRAWINGS

The above and other aspects, features and other advantages will be more clearly understood from the following detailed description taken in conjunction with the accompanying drawings, in which:

FIG. 1 shows the construction of the bandpass filter of an RF communication system in accordance with one embodiment of the present invention;

FIG. 2 is a graph showing a transmission characteristic of the bandpass filter of an RF communication system in accordance with one embodiment of the present invention;

FIG. 3 is a graph showing a distribution characteristic of the frequencies of the bandpass filter of an RF communication system in accordance with one embodiment of the present invention;

FIG. 4 is a graph showing a phase characteristic of the bandpass filter of an RF communication system in accordance with one embodiment of the present invention; and

FIG. 5 is a graph showing a ripple characteristic of the bandpass filter of an RF communication system in accordance with one embodiment of the present invention.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

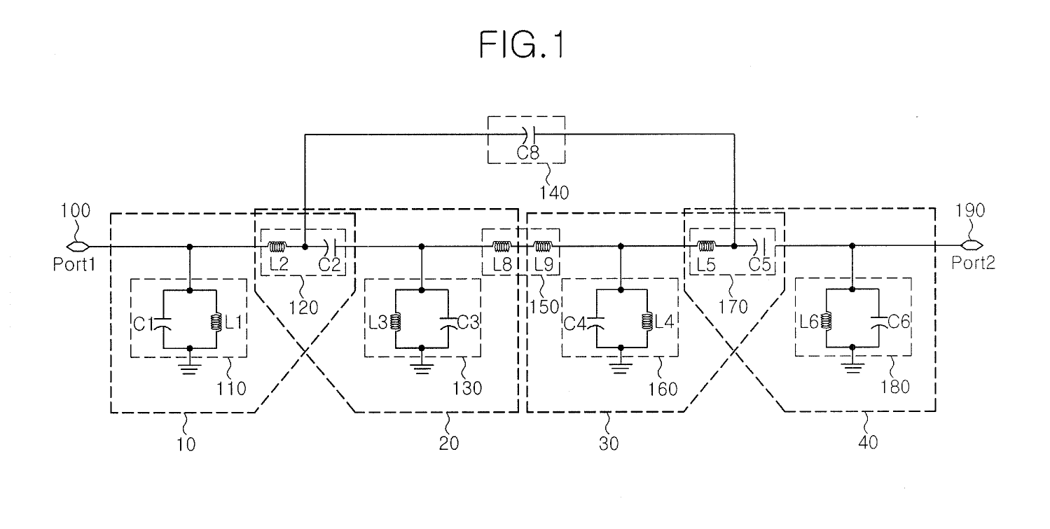

FIG. 1 shows the construction of the bandpass filter of an RF communication system in accordance with one embodiment of the present invention.

As shown in FIG. 1, the bandpass filter of an RF communication system in accordance with one embodiment of the present invention includes a first non-equilibrium zero-order resonator 10, a first equilibrium zero-order resonator 20, a second non-equilibrium zero-order resonator 40, a second equilibrium zero-order resonator 30, an induction coupling unit 150, and a cross-coupling unit 140.

The first non-equilibrium zero-order resonator 10 and the first equilibrium zero-order resonator 20 are connected in series to an input port 100.

The first non-equilibrium zero-order resonator 10 is connected to the input port 100, and the first equilibrium zero-order resonator 20 is connected to the inside of the bandpass filter.

The first equilibrium zero-order resonator 20 has a Composite Right Left Handed (CRLH) structure in which the first serial resonance unit 120 and the first parallel resonance unit 130, and the first serial inductor L8 of an induction coupling unit 150 have an equilibrium state. The first non-equilibrium zero-order resonator 10 has a CRLH structure, including the first serial resonance unit 120 and a second parallel resonance unit 110.

Furthermore, the first serial resonance unit 120 includes a serial inductor L2 and a serial capacitor C2. The first parallel resonance unit 130 and the second parallel resonance unit 110 include respective parallel inductors L1 and L3 and respective parallel capacitors C1 and C3.

The first serial resonance unit 120 is shared by the first equilibrium zero-order resonator 20 and the first non-equilibrium zero-order resonator 10.

The second non-equilibrium zero-order resonator 40 and the second equilibrium zero-order resonator 30 are connected in series to an output port 190.

The second non-equilibrium zero-order resonator 40 is connected to the output port 190, and the second equilibrium zero-order resonator 30 is connected to the inside of the bandpass filter.

The second equilibrium zero-order resonator 30 has a CRLH structure in which a second serial resonance unit 170 and a third parallel resonance unit 160, and the second serial inductor L9 of the induction coupling unit 150 have an equilibrium state. The second non-equilibrium zero-order resonator 40 has a CRLH structure, including the second serial resonance unit 170 and a fourth parallel resonance unit 180.

Furthermore, the second serial resonance unit 170 includes a serial inductor L5 and a serial capacitor C5. The third parallel resonance unit 160 and the fourth parallel resonance unit 180 include respective parallel inductors L4 and L6 and respective parallel capacitors C4 and C6.

The second serial resonance unit 170 is shared by the second equilibrium zero-order resonator 30 and the second non-equilibrium zero-order resonator 40.

The induction coupling unit 150 connects the first equilibrium zero-order resonator 20 to the second equilibrium zero-order resonator 30 by the coupling of the first serial inductor L8 and the second serial inductor L9.

The cross-coupling unit 140 includes the serial capacitor C8 connected in parallel to and branched from the first equilibrium zero-order resonator 20 and the second equilibrium zero-order resonator 30 and configured to generate transmission zero near a pass band, thereby improving a skirt characteristic of the pass band and providing a dual band matching characteristic.

The cross-coupling unit 140 is branched from a node of the serial inductors L2 and L5 of the first serial resonance unit 120 and from a node of the serial capacitors C2 and C5 of the second serial resonance unit 170 and is connected by the serial capacitor C8.

As described above, the bandpass filter for embodying a dual band characteristic is embodied by sequentially connecting the pair of first and second equilibrium zero-order resonators 20 and 30 and the pair of first and second non-equilibrium zero-order resonators 10 and 40 which are configured to have the same zero-order resonant frequency and which are coupled in series. Here, a zero-order resonant frequency and a band width are matched with the bandpass characteristic of the bandpass filter using the frequency distribution characteristic of the zero-order resonators, thereby being capable of making flat a pass band characteristic and uniform transmission zero due to a bandgap near a band.

Here, the bandpass filter is designed to include the zero-order resonators having a zero-order resonant frequency by controlling a band width using the frequency distribution characteristic and controlling a zero-order resonant frequency, that is, matching a transfer characteristic of each of the zero-order resonators with a transfer characteristic of the bandpass filter. Here, the first and the second equilibrium zero-order resonators 20 and 30 and the first and the second non-equilibrium zero-order resonators 10 and 40 have the same zero-order resonant frequency at the input and output terminals 100 and 190 of the bandpass filter, so that the band width of the zero-order resonant frequency of the zero-order resonator is suitable for the band width of the bandpass filter.

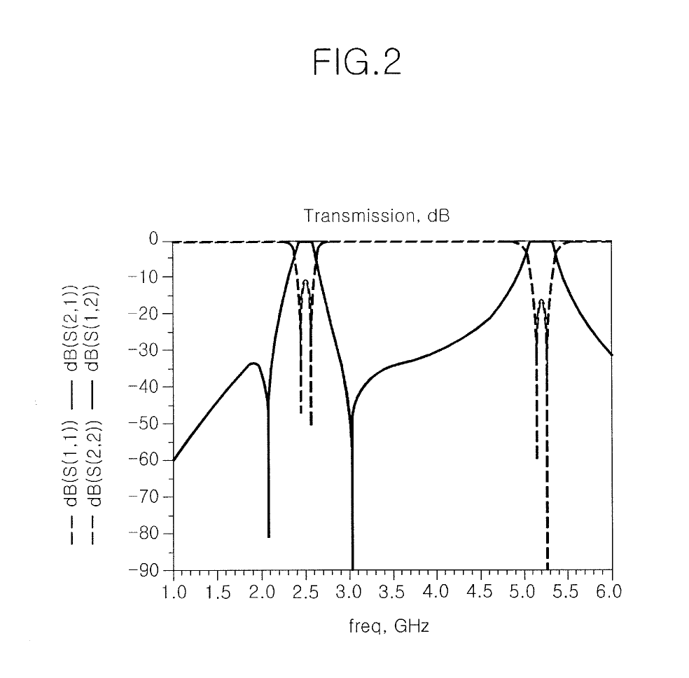

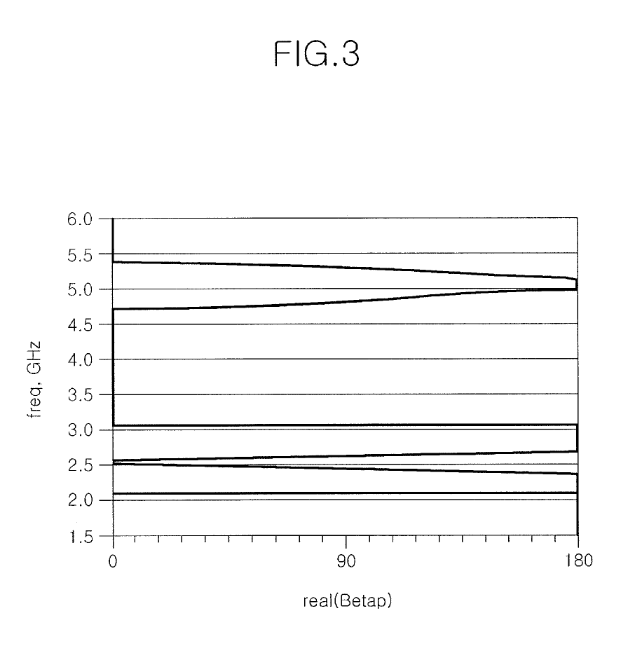

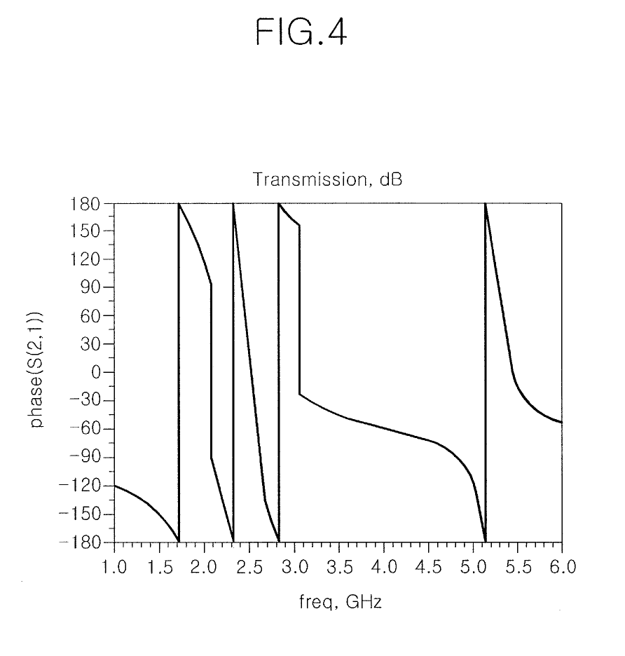

FIG. 2 is a graph showing a transmission characteristic of the bandpass filter of an RF communication system in accordance with one embodiment of the present invention, FIG. 3 is a graph showing a distribution characteristic of the frequencies of the bandpass filter of an RF communication system in accordance with one embodiment of the present invention, FIG. 4 is a graph showing a phase characteristic of the bandpass filter of an RF communication system in accordance with one embodiment of the present invention, and

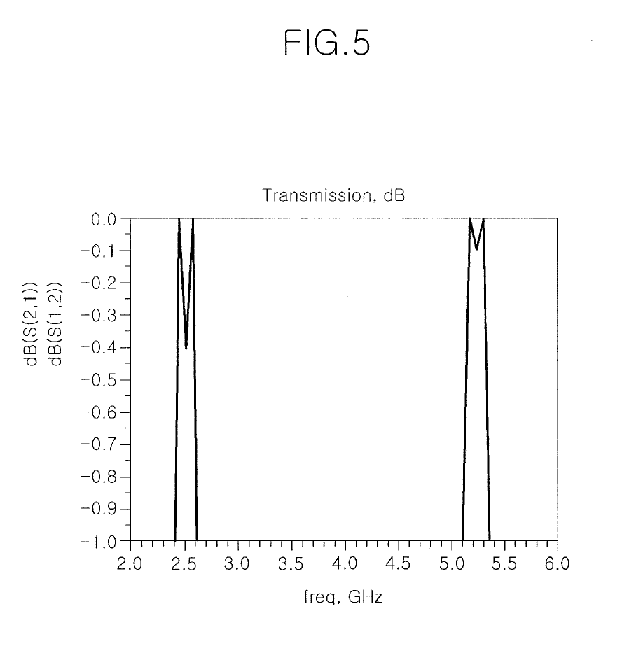

FIG. 5 is a graph showing a ripple characteristic of the bandpass filter of an RF communication system in accordance with one embodiment of the present invention.

As shown in FIG. 2, the bandpass filter has been designed to have a transmission characteristic of a dual band characteristic. In order to improve selectivity from the center of a low pass band, two transmission zeros are inserted and the bandpass filter has been designed to suppress a transmission characteristic after the transmission zeros suddenly.

Furthermore, the frequency distribution characteristic of FIG. 3 shows a frequency distribution diagram in which the entire bandpass filter is viewed as one cell and shows a dual band characteristic having two pass band. From FIG. 3, the characteristics of a pass band, transmission zero, and a blocking band can be seen.

Furthermore, FIGS. 4 and 5 are graphs showing the respective phase and ripple characteristics of the bandpass filter. From FIGS. 4 and 5, it can be seen that the transmission zero of a dual band and a low band and the slope characteristics of a blocking band are improved without deteriorating all characteristics of the bandpass filter.

As described above, the bandpass filter of an RF communication system in accordance with the present invention can embody a dual band characteristic by combining the equilibrium zero-order resonators and the non-equilibrium zero-order resonators and provide transmission zero using the cross-coupling structure near a pass band.

Furthermore, the present invention can provide the bandpass filter of an RF communication system having a neighboring signal blocking characteristic.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A bandpass filter of a Radio Frequency (RF) communication system, comprising:
a first non-equilibrium zero-order resonator and a first equilibrium zero-order resonator connected in series to an input port;
a second non-equilibrium zero-order resonator and a second equilibrium zero-order resonator connected in series to an output port;
an induction coupling unit configured to combine the first equilibrium zero-order resonator and the second equilibrium zero-order resonator; and
a cross-coupling unit connected in parallel to and branched from the first equilibrium zero-order resonator and the second equilibrium zero-order resonator.

2. The bandpass filter of claim 1, wherein:
in the first equilibrium zero-order resonator, a first serial resonance unit and a first parallel resonance unit, and a first serial inductor of the induction coupling unit have an equilibrium state, and
the first non-equilibrium zero-order resonator comprises the first serial resonance unit and a second parallel resonance unit.

3. The bandpass filter of claim 2, wherein the first serial resonance unit comprises a serial inductor and a serial capacitor.

4. The bandpass filter of claim 3, wherein the cross-coupling unit is branched from a node of the serial inductor of the first serial resonance unit and the serial capacitor and is connected by a serial capacitor.

5. The bandpass filter of claim 2, wherein each of the first parallel resonance unit and the second parallel resonance unit comprise a parallel inductor and a parallel capacitor.

6. The bandpass filter of claim 1, wherein:
in the second equilibrium zero-order resonator, a second serial resonance unit and a third parallel resonance unit, and a second serial inductor of the induction coupling unit have an equilibrium state, and
the second non-equilibrium zero-order resonator comprises the second serial resonance unit and a fourth parallel resonance unit.

7. The bandpass filter of claim 6, wherein the second serial resonance unit comprises a serial inductor and a serial capacitor.

8. The bandpass filter of claim 7, wherein the cross-coupling unit is branched from a node of the serial inductor of the second serial resonance unit and the serial capacitor and is connected by a serial capacitor.

9. The bandpass filter of claim 6, wherein each of the third parallel resonance unit and the fourth parallel resonance unit comprise a parallel inductor and a parallel capacitor.
